(19) United States
(12) Patent Application Publication
(10) Pub. No.: US 2012/0006583 A1
(43) Pub. Date: Jan. 12, 2012

(54) DISCHARGE GAP FILLING COMPOSITION AND ELECTROSTATIC DISCHARGE PROTECTOR

(75) Inventors: Yoshimitsu Ishihara, Tokyo (JP); Mina Onishi, Tokyo (JP); Yukihiko Azuma, Tokyo (JP)

(73) Assignee: SHOWA DENKO K.K., Minato-ku, Tokyo (JP)

(21) Appl. No.: 13/257,144

(22) PCT Filed: Mar. 17, 2010
(86) PCT No.: PCT/JP2010/054546

§ 371 Date: Sep. 16, 2011

(30) Foreign Application Priority Data
Mar. 19, 2009 (JP) 2009-067332

(51) Int. Cl. H05K 1/00; H01B 1/22; H01B 1/24; H05F 3/00; H05K 1/18; B82Y 99/00

(52) U.S. Cl. 174/254; 361/212; 174/260; 252/512; 252/513; 252/503; 977/753; 977/742

(57) ABSTRACT

The present invention provides an electrostatic discharge protector capable of simply taking ESD measures with a free shape against electronic circuit boards having various designs, having excellent regulation accuracy for an operating voltage and capable of downsizing and cost decreasing, and also provides a discharge gap filling composition capable of using in the production of the electrostatic discharge protector.

The discharge gap filling composition comprises metal particles (A) obtainable by metal particles with a hydrolyzed product of a metal alkoxide represented by the following formula (1) and a binder component (C), and the electrostatic discharge protector comprises the composition;

R—O—[M(OR)₂—O—]ₙ—R (1)
wherein M is a metal atom, O is an oxygen atom, R is an alkyl group, all or a part of R's may be the same as or different each other, and n is an integer of 1 to 40.

### TECHNICAL FIELD

The present invention relates to a discharge gap filling composition and an electrostatic discharge protector, more specifically it relates to an electrostatic discharge protector having excellent regulating accuracy at an operating voltage and capable of decreasing the size and the cost thereof and also relates to a discharge gap filling composition used for this electrostatic discharge protector.

### TECHNICAL BACKGROUND

Electrostatic discharge (hereinafter optionally referred to ESD) is one destructive and inevitable phenomenon that electric systems and integrated circuits are exposed. From the electric viewpoint, ESD is a transient high electric current phenomenon such that a peak current of several amperes continues for a period time of 10 n sec and 300 n sec. Therefore, the occurrence of ESD causes un-repairable damage, wrong conditions or deterioration in its integrated circuit, and thereby the integrated circuit does not work normally unless the electric current of several amperes is conducted to the outside of the integrated circuit within several ten nano sec. In recent years, furthermore, a marked tendency of weight decreasing, thickness decreasing and downsizing has proceeded in electronic parts and electronic equipments. According to the tendency, the integration degree of semiconductors and the packaging density of electronic parts in printed wiring boards are remarkably increased so that electronic elements and signal lines, which are densely integrated or mounted, are very closely present each other. Consequently, high-frequency radiation noise is easily induced together with the acceleration of the rate of signal processing.

Conventionally, as an electrostatic protection element for protecting IC and the like in a circuit from ESD, JP-A-2005-353845 discloses an element having a bulk structure which element comprises a sintered matter of a metal oxide or the like. This element is a laminated chip varistor formed from the sintered matter and is equipped with a laminate and a pair of external electrodes. The varistor has a property such that when an applied voltage reaches a certain definite value or more, a current, which has not flown until then, flows quickly, and also has excellent property capable of preventing electrostatic discharge. The laminated chip varistor, which is a sintered matter, is inevitably produced by a complicated process comprising sheet molding, internal electrode printing, sheet lamination and the like, and has a problem such that wrong conditions such as interlayer delamination and the like are easily induced during mounting steps.

Furthermore, as an electrostatic protection element for protecting IC and the like in circuits from ESD, there is a discharge type element. The discharge type element has a small leaked current, is fundamentally simple and is difficult to have breakdown. The discharge voltage thereof can be controlled by the distance of a discharge gap. When it has a sealing structure, the distance of the discharge gap is determined according to the pressure and the kind of a gas. As a substantially commercial element, there is an element obtainable by forming a conductor film on a cylindrical ceramic surface, providing a discharge gap on the film by a leaser and glass sealing. This commercial glass sealed tube type discharge gap element has excellent electrostatic discharge properties but a complicated formation. Therefore, it has problems such that the size thereof is limited as a small sized surface mounting element and the cost is hardly decreased.

Moreover, the following documents disclose a method of forming a discharge gap on a wiring directly and regulating a discharge voltage by the distance of the discharge gap. For example, JP-A-H3 (1991)-89588 discloses that the distance of a discharge gap is 4 mm, and JP-A-H5 (1995)-67851 discloses that the distance of a discharge gap is 0.15 mm. JP-A-H10 (1998)-27668 discloses that the discharge gap is preferably 5 to 60 μm in order to protect general electronic elements, the discharge gap is preferably 1 to 30 μm in order to protect IC or LSI sensitive to static electricity, and the discharge gap can be made to have a large size of about 150 μm in the use of only removing a large pulse voltage part.

Unless there is no protection for the discharge gap part, the application at a high voltage can cause aerial discharge, the moisture and gases in the environment can cause contamination on conductor surface and thereby the discharge voltage is changed, or the carbonization of a substrate provided with electrodes occasionally causes short circuit on the electrodes. Furthermore, since this electrostatic discharge protector is required to have high insulating resistance at a normal operating voltage, for example, at a voltage of less than DC10V, it is effective to provide a voltage resistant insulating member on the discharge gap of the electrode pair. When a resist is directly filled in the discharge gap as an insulating member in order to protect the discharge gap, it is not practical because the discharge voltage is vastly increased. When a usual resist is filled in a narrow discharge gap having a very narrow width of about 1 to 2 μm or less, the discharge voltage can be decreased, but the resist filled therein is minutely deteriorated and thereby the insulating resistance is lowered and conduction is occasionally caused.

JP-A-2007-266479 discloses a protective element such that a discharge gap having a width of 10 μm to 50 μm is provided on an insulating substrate and a functional film containing ZnO as a main component and silicon carbide is provided between a pair of electrode patterns which ends are faced each other. As compared with a laminated chip varistor, the protective element has a merit that the constitution is simple and the element can be produced as a thick film element on the substrate. These elements having measures for ESD are made to decrease the mounting area in accordance with the progress of electronic devices. However, the form thereof is an element and the design has low variation in order to mount on a wiring substrate by solder and the like and they have limits on downsizing including a height. Therefore, it is desired to take measures for ESD to necessary places and necessary areas with a free form including downsizing without fixing elements.

Meanwhile, WO-2001-523040 (Patent document 1) discloses a resin composition as an ESD protecting material. This resin composition comprises a main material of an insulating binder mixture, conductive particles having an average particle diameter of less than 10 μm and semiconductor particles having an average particle diameter of less than 10 μm. This document discloses U.S. Pat. No. 4,726,991 (Patent document 2) filed by Hyatt et al. The patent document 2 discloses a composition material in which a mixture of conductive particles having surfaces covered with an insulating oxide film and conductor particles is bonded with an insulating binder, a composition material having a defined particle diameter range, and a composition material having a defined surface distance between conductive particles. In the process of the document, the method of dispersing the conductive particles and semiconductor particles is not optimized. The process has technically unstable factors that a high electric resistance value is not obtained at a low voltage and a low electric resistance value is not obtained at a high voltage.

Moreover, a process for covering metal particles with a metal alkoxy compound is disclosed in JP-B-3170488 (Patent document 3), JP-A-2004-83628 (Patent document 4) and JP-A-2004-124069 (Patent document 5). These documents concern a colored aluminum powder pigment but do not disclose that the process applies on ESD protective materials by adding insulating properties on the metal surfaces.

### PRIOR ARTS

### Patent Documents

Patent document 1: WO-2001-523040
Patent document 2: U.S. Pat. No. 4,726,991
Patent document 3: JP-B-3170488
Patent document 4: JP-A-2004-83628
Patent document 5: JP-A-2004-124069

### SUMMARY OF THE INVENTION

### Subject to be Solved by the Invention

The present invention is intended to solve the above problems and it is an object of the present invention to provide an electrostatic discharge protector capable of simply preventing ESD with a free form in electronic circuit boards of various designs, having excellent regulation accuracy at an operating voltage and also capable of decreasing the size and cost, and it is another object of the invention to provide a discharge gap filling composition used for the production of the electrostatic discharge protector.

### Means for Solving the Subjects

The present inventors have been earnestly studied in order to solve the above problems in the prior arts and found that the electrostatic discharge protector having excellent regulation accuracy at an operating voltage and capable of decreasing the size and coat can be prepared by regulating a discharge gap of one pair of electrodes in a specific distance, filling the gap with a composition of specific components and solidifying or curing.

That is to say, the present invention relates to the following subjects.

[1] A discharge gap filling composition comprising metal particles (A) obtainable by covering metal particles with a hydrolyzed product of a metal alkoxide represented by the following formula (1) and a binder component (C).

R—O—[M(OR)₂—O—]ₙ—R (1)

In the formula (A), M is a metal atom, O is an oxygen atom, R is an alkyl group of 1 to 20 carbon atoms, all or a part of R's may be the same as or different each other, and n is an integer of 1 to 40.

[2] The discharge gap filling composition according to [1] wherein the element M in the formula (1) is silicon, titanium, zirconium, tantalum or hafnium.

[3] The discharge gap filling composition according to [1] or [2] wherein the metal particles of the metal particles (A) are oxide film coated metal particles.

[4] The discharge gap filling composition according to [3] wherein the metal of the oxide film coated metal particles is at least one selected from the group consisting of manganese, niobium, zirconium, hafnium, tantalum, molybdenum, vanadium, nickel, cobalt, chromium, magnesium, titanium and aluminum.

[5] The discharge gap filling composition according to any one of [1] to [4] further comprising a layered substance (B) together with the metal particles (A) and the binder component (C).

[6] The discharge gap filling composition according to [5] wherein the layered substance (B) is at least one selected from the group consisting of a clay mineral crystal (B1) and a layered carbon material (B2).

[7] The discharge gap filling composition according to [5] wherein the layered substance (B) is the layered carbon material (B2).

[8] The discharge gap filling composition according to [7] wherein the layered carbon material (B2) is at least one selected from the group consisting of carbon nano tube, gas phase grown carbon fiber, carbon fullerene, graphite and a carbyne carbon material.

[9] The discharge gap filling composition according to any one of [1] to [8] wherein the binder component (C) comprises a thermosetting or activated energy setting compound.

[10] The discharge gap filling composition according to any one of [1] to [8] wherein the binder component (C) comprises a thermosetting urethane resin.

[11] An electrostatic discharge protector comprising two electrodes for forming a discharge gap, and a discharge gap-filling member that is filled in the discharge gap wherein the discharge gap-filling member comprises the discharge gap filling composition as described in any one of [1] to [10] and the discharge gap has a distance of 5 to 300 μm.

[12] The electrostatic discharge protector according to [11] further comprising a protective layer which covers all or a part of the surface of the discharge gap-filling member.

[13] An electronic circuit board provided with the electrostatic discharge protector as described [11] or [12].

[14] The electronic circuit board according to [13], which is a flexible electronic circuit board.

[15] An electronic device provided with the electronic circuit board as described in [13] or [14].

### Effect of the Invention

The electrostatic discharge protector of the present invention can be formed by forming a discharge gap between necessary electrodes in accordance with a necessary operating voltage, filling the discharge gap with the discharge gap filling composition of the present invention and solidifying or curing. On this account, the use of the discharge gap filling composition of the present invention can produce a small size electrostatic discharge protector in low cost and realize electrostatic discharge protection simply. Since the use of the discharge gap filling composition of the present invention can regulate the operating voltage by regulating the discharge gap in a specific distance, the electrostatic discharge protector of the present invention has excellent regulating accuracy at an operating voltage. Furthermore, the electrostatic discharge protector of the present invention is suitably used for digital devices including cellular phones and mobile devices that they are frequently handled and static electricity is easily charged therein.

### BRIEF DESCRIPTION OF DRAWING

FIG. 1 is a vertical section of an electrostatic discharge protector 11, which is one embodiment of the electrostatic discharge protector according to the present invention.

FIG. 2 is a vertical section of an electrostatic discharge protector 21, which is one embodiment of the electrostatic discharge protector according to the present invention.

FIG. 3 is a vertical section of an electrostatic discharge protector 31, which is one embodiment of the electrostatic discharge protector according to the present invention.

FIG. 4 is a TEM image of the covered part of a surface coated metal particle (A) prepared in Preparation Example 1.

FIG. 5 is a graph of the results of element analysis (EDS) in the covered parts of the surface coated metal particles (A) prepared in Preparation Example 1.

### Embodiment FOR CARRYING OUT THE INVENTION

The present invention will be described in detail below.

### <Discharge Gap Filling Composition>

The discharge gap filling composition of the present invention comprises the metal particles (A) and the binder component (C), and optionally the layered substance (B).

### Metal Particles (A)

The metal particles (A) used in the present invention are obtainable by covering metal particles coated with a hydrolyzed product of a metal alkoxide represented by the formula (1).

R—O—[M(OR)₂—O—]ₙ—R (1)

In the formula, M is a metal atom, 0 is an oxygen atom, R is an alkyl group of 1 to 20 carbon atoms, all or a part of R's may be the same or different each other and n is an integer of 1 to 40.

The metal particles (A) (hereinafter, sometimes referred to “the surface coated metal particles (A)”) have insulating properties at a normal voltage because of partially having proper insulating properties and high voltage resistance. In high voltage loading at the time of electrostatic discharging, the metal particles (A) have conductive properties. Consequently, it is considered that in the case of using the metal particles (A) for the discharge gap filling composition of an electrostatic discharge protector, effective properties are exerted and electronic circuits equipped with this electrostatic discharge protector hardly receive breakage at a high voltage.

The metal alkoxide is not particularly limited unless it reacts with water singly or with water and a hydrolyzing catalyst to form a hydrolyzed product.

In the present invention, the metals constituting the metal alkoxide may include semimetals such as silicon, germanium and tin.

Preferable examples of the element M in the formula (1) are magnesium, aluminum, gallium, indium, thallium, silicon, germanium, tin, titanium, zirconium, hafnium, tantalum and niobium. Among them, silicon, titanium, zirconium, tantalum and hafnium are furthermore preferred, and silicon is particularly preferred. The silicon alkoxide is hardly hydrolyzed by moisture in the air, the hydrolyzing rate can be easily controlled and the production stability is enhanced.

R in the formula (1) is an alkyl group having 1 to 20 carbon atoms, preferably having 1 to 12 carbon atoms, and examples thereof are methyl, ethyl, n-propyl, isopropyl, n-butyl, sec-butyl, tert-butyl, n-pentyl, 1-methylbutyl, 2-methylbutyl, 3-methylbutyl, neopentyl, 1-ethylpropyl, n-hexyl, 1,1-dimethylpropyl, 1,2-dimethylpropyl, 1,2-dimethylpropyl, 1-methylpentyl, 2-methylpentyl, 3-methylpentyl, 4-methylpentyl, 1,1-dimethylbutyl, 1,2-dimethylbutyl, 1,3-dimethylbutyl, 2,2-dimethylbutyl, 2,3-dimethylbutyl, 3,3-dimethylbutyl, 1-ethylbutyl, 2-ethylbutyl, 1,1,2-trimethylpropyl, 1,2,2-trimethylpropyl, 1-ethyl-1-methylpropyl, 1-ethyl-2-methylpropyl, n-heptyl, n-octyl, n-nonyl, n-decyl and n-dodecyl. Preferable examples of the alkyl group are methyl, ethyl, n-propyl, isopropyl, n-butyl, sec-butyl, isobutyl and n-pentyl. More preferable examples are ethyl, n-propyl and n-butyl.

The above alkyl groups are preferred because the alkyl group having a larger molecular weight has more moderate hydrolysis, and when the molecular weight is too large, the alkyl group is in a wax state and it is difficult to be dispersed uniformly.

In the case that when a monomer (n=1 in the formula (1)) is used, the reaction rapidly occurs and many suspended particles generate, it is desired to use a condensate such as a dimer (n=2 in the formula (1)), a trimer (n=3 in the formula (1)) and a tetramer (n=4 in the formula (1)). When the number n is too large, the viscosity of the metal alkoxide itself is increased and the metal alkoxide is hardly dispersed. Therefore, n is preferably 1 to 4.

Examples of the metal alkoxide used in the present invention are tetramethoxy silane, tetraethoxy silane, tetraethyl titanate, tetraisopropyl titanate, tetra-n-butyl titanate, tetra-sec-butyl titanate, tetra-tert-butyl titanate, tetra-2-ethylhexyl titanate, tetraethyl zirconate, tetraisopropyl zirconate, tetra-n-butyl zirconate, tetra-sec-butyl zirconate, tetra-tert-butyl zirconate, tetra-2-ethylhexyl zirconate and condensates thereof. Particularly, tetraethoxy silane is preferred in the points of hydrolyzing properties and dispersibility. The metal alkoxides may be used singly or two or more may be mixed for use.

Examples of the metal particles contained in the surface coated metal particles (A) may include known metal particles and further preferably oxide film coated metal particles. The oxide film coated metal particles are obtainable by forming films of an oxide of the metal on the surfaces of the particles of the metal. The oxide film coated metal particles have insulating properties at a normal voltage because the oxide films have insulating properties, but it is considered that they have conducting properties at a high voltage load in electrostatic discharging and the insulating properties recover by release of a high voltage.

Preferable examples of the metal particles are metal particles capable of protecting their insides by forming minute oxide films on the surfaces in spite of having a high ionizing tendency, namely, capable of forming a passive state. Examples of the metal of metal particles are manganese, niobium, zirconium, hafnium, tantalum, molybdenum, vanadium, nickel, cobalt, chromium, magnesium, titanium and aluminum. Most preferable examples are aluminum, nickel, tantalum and titanium because they are easily available at a small cost. The metal may be an alloy of their metals. It is effective to use the vanadium particles used for a thermister, which resistance value quickly changes at a specific temperature. The metal particles of one kind can be used singly or two or more kinds can be mixed for use.

The oxide film coated metal particles can be prepared by heating metal particles in the presence of oxygen and further oxide films having a more stable structure can be prepared in the following method. That is to say, in order that the insulating breakage voltage of the oxide film on the metal surface is not uneven in one device or between devices, for example, the surfaces of metal particles are cleaned by an organic solvent such as acetone, and slightly etched by dilute hydrochloric acid. Furthermore, the metal particle surfaces are heated in an atmosphere of a mixed gas of 20% of hydrogen and 80% of argon at a temperature lower than the melting point of the metal itself, i.e. at 750° C. in the metals other than aluminum, at 600° C. in aluminum, for about 1 hr and further heated at an atmosphere of high purity oxygen for 30 min with the result that the uniform oxide films can be formed with high controllability and good reproducibility.

In order to cover the surfaces of the metal particles by the hydrolyzed product of the metal alkoxide represented by the formula (1), there is a practicable method such that the metal alkoxide and water in an amount capable of hydrolyzing it are gradually added to a solvent in which the metal particles are suspended and thereby the hydrolyzed product is deposited on the metal particle surfaces.

According to the method, it is considered that when M is a silicon atom, an oligomer, a polymer and their mixtures in the form of dehydrated and condensed silicon dioxide and silanol are generated on the metal particle surfaces by hydrolysis.

Examples of the method of adding the metal alkoxide and water are a method of adding inclusively and a method of adding them in a small amount several times by several steps. With regard to the addition order, the metal alkoxide may be previously dissolved or suspended in the solvent followed by adding water, water may be previously dissolved or suspended in the solvent followed by adding the metal alkoxide, or small amounts of the metal alkoxide and water may be added to the solvent one after the other. However, it is desired that the metal alkoxide and water are respectively diluted with the solvent to decrease the concentration and small amounts thereof are added to the solvent several times.

Preferable examples of the solvent may include alcohols and materials capable of dissolving the metal alkoxide such as mineral spirit, solvent naphtha, benzene, toluene, xylene and petroleum benzene. They are not limited particularly because they react in a suspended state. Furthermore, they may be used singly or in a mixture of two or more. Moreover, since in the hydrolysis reaction of the metal alkoxide, alcohol is produced as a byproduct by adding water, it is possible to add alcohol as a regulating agent for polymerization rate.

Through the covering step, the film thickness of the surface coated metal particles (A) can be determined to be about 5 to 40 nm. The coated film thickness can be measured by a conventional transmission electron microscope. With regard to the covering region, a part of the surface of each metal particle may be covered but all surface of each metal particle is preferably covered.

The particle diameters of the metal particles contained in the surface coated metal particles (A) differ depending on the distance of a pair of opposing electrodes (discharge gap distance) forming the discharge gap. The average particle diameter is preferably not less than 0.01 μm and not more than 30 μm. When the average particle diameter of the metal particles having oxide films is more than 30 μm the oxidation of the surface films which have been broken by reduction at the time of ESD occurrence is delayed and the recovery of the insulating properties is delayed because the amount of the oxide films per unit weight of the metal particles is smaller as compared with the amount of the internal conductive parts which are not oxidized. When the average particle diameter is less than 0.01 μm, in the weight proportion of the oxide film and the conductive part per unit weight, the weight of the oxide film becomes large and thereby the operating voltage at the time of ESD occurrence is occasionally increased. The average particle diameter is evaluated by a 50% cumulative mass diameter. The 50% cumulative mass diameter is obtainable by adding 1% by mass of metal particles for measurement to methanol, dispersing for 4 min by means of an ultrasonic homogenizer at a 150 W output and measuring by means of a laser diffraction type light scattering particle size distribution meter Microtrac MT3300 (manufactured by Nikkiso Co., Ltd.).

The surface coated metal particles (A) have surfaces showing insulating properties so that they may be as well present in contact with each other. However, when the proportion of the binder component is small, a problem such as powder falling and the like is occasionally induced. Therefore, in consideration of practicability rather than operating properties, the volume occupancy of the surface coated metal particles (A) in the solid components of the discharge gap filling composition is desirably less than 80% by volume.

At the time of ESD occurrence, the electrostatic discharge protector as a whole needs to show conducting properties. The volume occupancy of the surface coated metal particles (A) has the preferable minimum. The volume occupancy of the surface coated metal particles (A) in the solid components of the discharge gap filling resin composition is desirably not less than 30% by volume. Namely, the volume occupancy of the surface coated metal particles (A) is preferably not less than 30% by volume and less than 80% by volume.

The volume occupancy can be determined by subjecting the cross section of a cured product of the discharge gap filling composition to energy dispersion type X-ray analysis by mean of a scanning electron microscope JSM-7600F (manufactured by JEOL Ltd.), and evaluating with the volume proportion of the observation field that the resulting element occupies.

In the case of preparing the discharge gap filling composition, the mass occupancy is easily used in order to control. The mass occupancy of the surface coated metal particles (A) in the solid components of the discharge gap filling resin composition is preferably not less than 30% by mass and not more than 95%.

### Layered Substance (B)

The composition of the present invention preferably comprises the layered substance (B) from the viewpoint of attaining good ESD protecting properties. The layered substance (B) is a substance formed by a plurality of layers combined through van der Waals force, which substance is a compound such that an atom, molecule or ion which is not concerned with the crystal inherently can be incorporated at a specific position of the crystal by ion exchange and thereby the crystal structure is not changed. The position where an atom, molecule or ion incorporates, that is, the host position has a planar layer structure. Typical examples of the layered substance (B) are a clay mineral crystal (B1), a layered carbon material (B2) such as graphite, and a transition metal chalcogenide compound. These compounds exhibit unique properties by incorporating a metal atom, inorganic molecule or organic molecule as a guest in their crystals.

The layered substance (B) has a property that the distance of the layers is flexibly corresponding with the size of a gust and the interaction of the gust. The compound obtainable by incorporating the gust into the host is called as an intercalation compound and there are very various intercalation compounds in combination of the host and the gust. The gust in the layers is different from one adsorbed on the surface and is present in a peculiar environment that it is constrained by the host layers from the two directions. Therefore, it is considered that the property of the intercalation compound is dependent on not only the structure and property of each gust but also the host-guest interaction. Moreover, recently, the layered substance (B) has been studied on the points that it absorbs electromagnetic wave well and when the guest is an oxide, it becomes an oxygen absorbing and releasing material capable of absorbing or releasing oxygen at a certain temperature. It is considered that these properties cause interaction with a metal alkoxide hydrolyzed product or an oxide film with the result that the ESD protecting properties are improved.

Examples of the clay mineral crystal (B1) in the layered substance (B) used in the present invention may include smectites clay, which is a swelling silicate, and swelling mica. Specific examples of the smectites clay are montmorillonite, beidellite, nontronite, saponite, ferrous saponite, hectorite, sauconite, stevensite and bentonite, and their substituents and derivatives, and mixtures thereof. Specific examples of the swelling mica are lithium type taeniolite, sodium type taeniolite, lithium type tetrasilicic mica and sodium type tetrasilicic mica, and their substituents and derivatives, and mixtures thereof. Some of the swelling micas have the structure same as that of vermiculite and it is also possible to use such an equivalent for vermiculite.

As the layered substance (B) used in the present invention, the layered carbon material (B2) can be also used. The layered carbon material (B2) can release free electrons in the space between the electrodes at the time of ESD occurrence. The layered carbon material (B2), further, reduces a metal oxide because of heat storing at the time of ESD occurrence, and causes phase transition of the lattice structure of the oxide film interface by the heat to change the Schottky rectification properties. As a result, the oxide film coated metal particles showing insulating properties are changed to show conductive properties. Moreover, in the layered carbon material (B2), the internal resistance is increased by oxidation with oxygen generated at the time of over charging, but after the ESD occurrence, the layered carbon material (B2) is an oxygen-feeding source for reproducing the oxide films of the metal particles.

Examples of the layered carbon material (B2) are a substance obtainable by treating cokes at a low temperature, carbon black, a metal carbide, carbon whisker and SiC whisker. It is confirmed that they have operating properties for ESD. Since they have a carbon atom hexagonal network basic structure, a relatively small layer number and a relatively low regularity, they tend to easily get into short circuit. Therefore, preferable examples of the layered carbon material (B2) are carbon nano tube, gas phase grown carbon fiber, carbon fullerene, graphite and a carbine type carbon material because they have regularity in lamination. The layered carbon material (B2) desirably contains at least one of them or a mixture thereof. Furthermore, recently the fibrous layered carbon material (B2), such as carbon nano tube, graphite whisker, filamentous carbon, graphite fiber, superfine carbon tube, carbon tube, carbon fibril, carbon micro tube and carbon nano fiber have been industrially noticed on not only mechanical strength but also electric field liberating function and hydrogen storage function. The properties are considered to relate an oxidation-reduction reaction of the oxide film coated metal particles (A). Moreover, it is possible to mix the layered carbon material (B2) and an artificial diamond.

In particular, the hexagonal crystal carbon material which is a hexagonal plate-like flat crystal, the trigonal or rhomb face crystal graphites having high lamination regularity and the carbine type carbon material having a structure such that carbon atoms form a straight chain, and in the straight chain, a single bond and a triple bond are arranged repeatedly or carbon atoms are bonded with a double bond are suitable as a catalyst capable of promoting the oxidation and the reduction of the metal particles because other atoms, ions or molecules can be easily intercalated between the layers. Namely, the layered carbon materials (B2) indicated herein are characterized in that they can intercalate any of an electron donor and an electron acceptor.

In order to remove impurities, the layered carbon materials (B2) may be previously treated at a high temperature of about 2500 to 3200° C. in an inert gas atmosphere or at a high temperature of about 2500 to 3200° C. in an inert gas atmosphere together with a graphitizing catalyst such as boron, boron carbide, beryllium, aluminum or silicon.

As the layered substance (B), the clay mineral crystal (B1) such as swelling silicate and swelling mica, and the layered carbon material (B2) may be individually used or two or more may be combined for use. Among them, smectites group clay, graphite and gas phase grown carbon fiber are preferably used because of having dispersibility in the binder component (C) and easiness in acquisition.

When the layered substance [B] has a spherical or scale-like form, the average particle diameter is preferably not less than 0.01 μm and not more than 30 μm.

In the case that the average particle diameter of the layered substance (B) is over 30 μm, particularly in the layered carbon material (B2), continuity in particles is easily induced and thereby it is sometimes difficult to prepare a stable ESD protector. On the other hand, in the case that it is less than 0.01 μm, it has high cohesive force and production problems such as high charging properties and the like are sometimes induced. When the layered substance (B) has a spherical or scale-like form, the average particle diameter is evaluated by a 50% cumulative mass diameter in the following manner. 50 mg of a sample is weighed and added to 50 mL of distilled water. Furthermore, 0.2 mL of a 2% Triton aqueous solution (Trade name, a surface active agent manufactured by GE Health Care Bio Science Co. Ltd.) was added to the mixture and dispersed with an ultrasonic homogenizer of a 150 W output for 3 min, and then measured by a leaser diffraction type particle size distribution meter, for example, leaser diffraction light scattering type particle size distribution meter (Trade Mark: Microtrac MT3300, manufactured by Nikkiso Co., Ltd.).

The layered substance (B) having a fibrous form preferably has an average fiber diameter of not less than 0.01 μm and not more than 0.3 μm, and an average fiber length of not less than 0.01 μm and not more than 20 μm, and more preferably an average fiber diameter of not less than 0.06 μm and not more than 0.2 μm, and an average fiber length of not less than 1 μm and not more than 20 μm. The average fiber diameter and the average fiber length of the fibrous layered substance (B) can be determined by measuring, for example, 20 to 100 fibers with an electron microscope and taking an average.

In the case that the layered carbon material (B2) is used as the layered substance (B), continuity of the carbon materials (B2) between the electrodes must be avoided in order to keep the insulating properties at the time of normal operating. Therefore, the volume occupancy of the layered carbon material (B2) is important in addition to the dispersibility and the average particle diameter. In the case that the clay mineral crystal (B1) such as swelling silicate and swelling mica is used as the layered substance (B), it is sufficiently effective to add it in an amount of capable of partly damaging the oxide films of the metal particles.

Therefore, in the layered substance (B) having a spherical or scale-like form, the volume occupancy of the layered carbon material (B2) is desirably not less than 0.1% by volume and not more than 10% by volume in the solid components of the discharge gap-filling resin composition. When the volume occupancy is more than 10% by volume, continuity in the carbon atoms is easily induced and thereby the resin or substrate is broken because the heat reserve is large at the time of ESD discharging, and after ESD generation, the recovery of the insulating properties of an ESD protector tends to be late by high temperatures. On the other hand, when it is less than 0.1% by volume, the operating properties for ESD protection is sometimes unstable.

The layered substance (B) having a fibrous form is more effectively contact with the surfaces of the metal particles (A) as compared with the layered substance (B) having a spherical or scale-like form, and it is easily conducted by the excess amount thereof. Therefore, the layered substance (B) having a fibrous form has preferably a little volume occupancy of not less than 0.01% by volume and not more than 5% by volume as compared with the layered substance (B) having a spherical or scale-like form.

In the case of preparing the discharge gap filling composition, the mass occupancy is used for easy control, and the mass occupancy of the layered substance (B) is preferably not less than 0.01% by mass and not more than 5% by mass in the solid components of the discharge gap filling resin composition.

### Binder Component (C)

The binder component (C) of the present invention is an insulating substance capable of dispersing the surface coated metal particles (A) and the layered substance (B) therein. Examples of the binder component (C) are organic polymers, inorganic polymers and their mixed polymers.

Examples of the binder component (C) are a polysiloxane compound, a urethane resin, a polyimide, a polyolefin, a polybutadiene, an epoxy resin, a phenol resin, an acryl resin, a hydrogenated polybutadiene, a polyester, a polycarbonate, a polyether, a polysulfone, a polytetrafluororesin, a melamine resin, a polyamide, a polyamide imide, a phenol resin, an unsaturated polyester resin, a vinyl ester resin, an alkyd resin, a diallylphthalate resin, an allylester resin and a furane resin.

The binder component (C) preferably contains a thermosetting or active energy curing compound from the viewpoints of mechanical stability, thermal stability, chemical stability or stability with time. Among them, a thermosetting urethane resin is particularly preferred because of having a high insulating resistance value, good adhesion with a base material and good dispersibility of the surface coated metal particles (A).

The above binder component (C) may be used singly or two or more may be combined for use.

Examples of the thermosetting urethane resin are polymers having a urethane linkage formed by allowing a polyol compound containing a carbonate diol compound to react with an isocyanate compound. Furthermore preferable examples thereof are a carboxyl group containing thermosetting urethane resin having a carboxyl group in its molecule and an acid anhydride group containing thermosetting urethane resin having an acid anhydride group in its molecular end. Examples of other curing components may include an epoxy resin curing agent and the like, and they can be used as one of the binder components (C).

Examples of the carbonate diol compound are a carbonate diol compound having a repeating unit derived from one or two or more straight chain aliphatic diols as a constituting unit, a carbonate diol compound having a repeating unit derived from one or two or more alicyclic diols as a constituting unit, and a carbonate diol compound having a repeating unit derived from both of the above diols as a constituting unit.

Examples of the carbonate diol compound having a repeating unit derived from the straight chain aliphatic diol as a constituting unit may include polycarbonate diols having a structure of bonding, with a carbonate linkage, a diol component such as 1,3-propane diol, 1,4-butane diol, 1,5-pentane diol, 1,6-hexane diol, 3-methyl-1,5-pentane diol, 2-methyl-1,8-octane diol and 1,9-nonane diol. Examples of the carbonate diol compound having a repeating unit derived from the alicyclic diol as a constituting unit may include polycarbonate diols having a structure of bonding, with a carbonate linkage, a diol component such as 1,4-cyclohexane dimethanol, 1,3-cyclohexane dimethanol, 1,4-cyclohexane diol, 1,3-cyclohexane diol, tricyclohexane dimethanol and pentacyclopentadecane dimethanol. Two or more of these diol components may be combined.

Commercially available examples of the carbonate diol compounds are Trade Names PLACCEL, CD-205, 205PL, 205HL, 210, 210PL, 210HL, 220, 220PL and 220HL manufactured by Daicel Chemical Industries, Ltd.; Trade Names UC-CARB100, UM-CARB90 and UH-CARB100 manufactured by Ube Industries Ltd.; and Trade Names C-1065N, C-2015N, C-1015N and C-2065N manufactured by Kuraray Co., Ltd. These carbonate diol compounds may be used singly or two or more may be combined for use. In particular, when the polycarbonate diol having a repeating unit derived from the straight chain aliphatic diol as a constituting unit is used, it tends to prepare a discharge gap filling member having low warpage properties and excellent flexibility and thereby the electrostatic discharge protector is easily provided on a flexible wiring board. When the polycarbonate diol having a repeating unit derived from the alicyclic diol as a constituting unit is used, it tends to prepare a discharge gap filling member having higher crystallinity and more excellent heat resistance. From the above viewpoints, it is preferred to use these polycarbonate diols in combination with two or more, or to use a polycarbonate diol containing both of the repeating units derived from the straight chain aliphatic diol and the alicyclic diol as constituting units. In order to exhibit well-balanced flexibility and heat resistance, it is preferred to use a polycarbonate diol having a mass ratio of straight chain aliphatic diol and alicyclic diol of from 3:7 to 7:3.

The carbonate diol compound has a number average molecular weight of preferably not more than 5000. When the number average molecular weight is over 5000, the relative amount of the urethane linkage decreases with the result that, sometimes, the operating voltage of an electrostatic discharge protector is increased or the high voltage resistance is decreased.

Examples of the isocyanate compound are 2,4-toluene diisocyanate, 2,6-toluene diisocyanate, isophorone diisocyanate, hexamethylene diisocyanate, diphenylmethylene diisocyanate, (o, m or p)-xylene diisocyanate, (o, m or p)-hydrogenated xylene trimethylhexamethylene diisocyanate, cyclohexane-1,3-dimethylene diisocyanate, cyclohexane-1,4-dimethylene diisocyanate, 1,3-trimethylene diisocyanate, 1,4-tetramethylene diisocyanate, 2,2,4-trimethylhexamethylene diisocyanate, 2,4,4-trimethylhexamethylene diisocyanate, 1,9-nonamethylene diisocyanate, 1,10-decamethylene diisocyanate, 1,4-cyclohexane diisocyanate, 2,2′-diethylether diisocyanate, cyclohexane-1,4-dimethylene diisocyanate, 1,5-naphthalene diisocyanate, p-phenylene diisocyanate, 3,3′-methylene ditolylene-4,4′-diisocyanate, 4,4′-dipheylether diisocyanate, 4,4′-diphenylmethane diisocyanate, tetrachlorophenylene diisocyanate, norbornane diisocyanate, 1,5-naphthalene diisocyanate and other diisocyanates. These isocyanate compounds may be used singly or two or more may be combined for use.

Among them, it is preferred to use alicyclic diisocyanates derived from alicyclic diamine such as isophorone diisocyanate or (o, m or p)-hydrogenated xylene diisocyanate. Using these diisocyanates, a cured product having excellent high voltage resistance can be prepared.

To prepare the carboxyl group containing thermosetting urethane resin as the thermosetting urethane resin of the present invention, a carboxyl group-having polyol is reacted with the carbonate diol compound and the isocyanate compound.

As the carboxyl group-having polyol, it is preferred to use a carboxyl group-having dihydroxy aliphatic carboxylic acid. Examples of such a di-hydroxyl compound are dimethylol propionic acid and dimethylol butanoic acid. Using the carboxyl group-having dihydroxy aliphatic carboxylic acid, a carboxyl group can be easily present in the urethane resin.

For preparing the acid anhydride group containing thermosetting urethane resin as the thermosetting urethane resin according to the present invention, for example, the carbonate diol compound is allowed to react with the isocyanate compound in a proportion of number of isocyanate group to number of hydroxyl group of not less than 1.01 to prepare a second diisocyanate compound, and then the second diisocyanate compound is allowed to react with an acid anhydride group having polycarboxylic acid or its derivative.

Examples of the acid anhydride group-having polycarboxylic acid or its derivative are an acid anhydride group-having trivalent polycarboxylic acid and its derivative, and an acid anhydride group-having tetra valent polycarboxylic acid.

Particularly non-limiting examples of the acid anhydride group-having trivalent polycarboxylic acid and its derivative may include compounds represented by the following formulas (2) and (3).

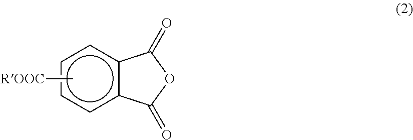

In the formula, R′ is hydrogen atom or an alkyl group of 1 to 10 carbon atoms or a phenyl group.

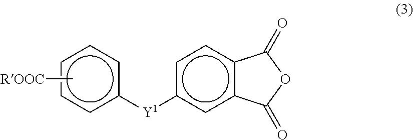

In the formula, Y¹ is —CH₂—, —CO—, —SO₂— or —O—.

As the acid anhydride group-having trivalent polycarboxylic acid, trimellitic acid anhydride is particularly preferred from the viewpoints of heat resistance and cost.

In addition to the above polycarboxylic acids and their derivatives, it is possible to use, in accordance with necessity, tetracarboxylic acid di-anhydrides (such as pyromellitic acid dianhydride, 3,3′,4,4′-benzophenone tetracarboxylic acid dianhydride, 3,3′,4,4′-biphenyl tetracarboxylic acid dianhydride, 3,3′,4,4′-diphenylsulfone tetracarboxylic acid dianhydride, 1,2,5,6-naphthalene tetracarboxylic acid dianhydride, 2,3,5,6-pyridine tetracarboxylic acid dianhydride, 1,4,5,8-naphthalene tetracarboxylic acid dianhydride, 3,4,9,10-perylene tetracarboxylic acid dianhydride, 4,4′-sulfonyl diphthalic acid dianhydride, m-terphenyl-3,3′,4,4′-tetracarboxylic acid dianhydride, 4,4′-oxy diphthalic acid dianhydride, 1,1,1,3,3,3-hexafluoro-2,2-bis(2,3- or 3,4-dicarboxy phenyl)propane dianhydride, 2,2-bis(2,3- or 3,4-dicarboxy phenyl)propane dianhydride, 2,2-bis[4-(2,3- or 3,4-dicarboxy phenoxy)phenyl]propane dianhydride, 1,1,1,3,3,3-hexafluoro-2,2-bis[4-(2,3- or 3,4-dicarboxy phenoxy)phenyl]propane dianhydride, 1,3-bis(3,4-dicarboxyphenyl)-1,1,3,3-tetramethyl disiloxane dianhydride, butane tetracarboxylic acid dianhydride and bicyclo-[2,2,2]-octo-7-en-2,3,5,6-tetracarboxylic acid dianhydride); aliphatic dicarboxylic acids (such as succinic acid, glutaric acid, adipic acid, azelaic acid, suberic acid, sebacic acid, decanoic diacid, dodecanoic diacid and dimer acid); aromatic dicarboxylic acids (such as isophthalic acid, terephthalic acid, phthalic acid, naphthalene dicarboxylic acid and oxy dibenzoic acid).

In the production of the thermosetting urethane resin, it is preferred to use a monohydroxyl compound as an end sealing agent, which is a compound containing one hydroxyl compound in its molecule, such as an aliphatic alcohol and a monohydroxymono(meth)acrylate compound. Herein, (meth)acrylate means acrylate and/or methacrylate, and it also refers below.

Examples of the aliphatic alcohol are methanol, ethanol, propanol, isobutanol, and an example of the monohydroxy mono(meth)acrylate compound is 2-hydroxyethyl acrylate. Using theses compounds, isocyanate group does not remain in the thermosetting urethane resin.

In order to add flame retardance, a halogen atom such as chlorine atom or bromine atom, and a phosphorus atom and the like may be introduced to the structure of the thermosetting urethane resin.

In the reaction excluding preparing the acid anhydride group containing thermosetting urethane resin, the proportion of the carbonate diol compound and the isocyanate compound (amount by mole of carbonate diol compound):(amount by mole of isocyanate compound) is preferably 50:100 to 150:100, more preferably 80:100 to 120:100.

In particular, in the case of preparing the carboxyl group containing thermosetting urethane resin by reacting a carboxyl group containing polyol together with the carbonate diol compound and the isocyanate compound, the amount by mole of the carbonate diol compound represented by (A), the amount by mole of the isocyanate compound represented by (B) and the amount by mole of the carboxyl group containing polyol represented by (C) satisfy the following blend proportion, (A)+(B):(C)=50 to 100 to 150:100, preferably (A)+(B):(C)=80 to 100 to 120:100.

In the reaction of the carbonate diol compound containing polyol compound and the isocyanate compound, preferably usable solvents are nitrogen free polar solvents. For example, examples of an ether solvent are diethyleneglycol dimethylether, diethylene glycol diethylether, triethyleneglycol, dimethylether and triethyleneglycol diethylether. Examples of a sulfur solvent are dimethylsulfoxide, diethyl sulfoxide, dimethyl sulfone and sulfolane. Examples of an ester solvent are γ-butylolactone, diethylene glycol monomethylether acetate, ethylene glycol monomethylether acetate, propylene glycol monomethylether acetate, diethylene glycol monoethyl ether acetate, ethylene glycol monoethyl ether acetate and propylene glycol monoethylether acetate. Examples of a ketone solvent are cyclohexanone and methylethyl ketone. Examples of an aromatic hydrocarbon solvent are toluene, xylene and petroleum naphtha. Theses may be used singly or two or more may be combined for use. Examples of the solvent having high volatility and capable of giving low temperature curing properties are γ-butylolactone, diethylene glycol monomethylether acetate, ethylene glycol monomethylether acetate, propylene glycol monomethylether acetate, diethylene glycol monoethylether acetate, ethylene glycol monoethylether acetate and propylene glycol monoethyl ether acetate.

In the reaction of the carbonate diol compound containing polyol compound and the isocyanate compound, the temperature is preferably 30 to 180° C., more preferably 50 to 160° C. When the temperature is lower than 30° C., the reaction prolongs too much time; while when it is over 180° C., gelation is easily caused.

The reaction time, which depends on the reaction time, is preferably 2 to 36 hr, more preferably 8 to 16 hr. When the reaction time is less than 2 hr, it is difficult to control even if the reaction temperature is increased in order to prepare the desired number average molecular weight. While when it is over 36 hr, it is not practical.

The thermosetting urethane resin has a number average molecular weight of preferably 500 to 100,000, more preferably 8,000 to 50,000. The number average molecular weight is a value converted to polystyrene measured by a gel permeation chromatography. When the thermosetting urethane resin has a number average molecular weight of less than 500, the elongation, flexibility and strength of a resulting discharge gap-filling member are sometimes damaged; while when it has that of over 100,000, a resulting discharge gap-filling member is rigid and has lowered flexibility.

The carboxyl group containing thermosetting urethane resin has an acid value of preferably 5 to 150 mgKOH/g, more preferably 30 to 120 mgKOH/g. When the acid value is less than 5 mgKOH/g, the reactivity with the curing components is lowered with the result that a resulting discharge gap-filling member, sometimes, does not have desired heat resistance and long time reliability. When the acid value is over 150 mgKOH/g, the flexibility of a resulting discharge gap-filling member is easily spoiled and the long time insulating properties are likely lowered. The acid value of a resin is a value determined in accordance with JIS K5407.

### Other Components

The discharge gap filling composition of the present invention may optionally comprise a curing catalyst, a curing accelerating agent, a filler, a solvent, a foaming agent, a defoaming agent, a leveling agent, a lubricant, a plasticizer, a rust preventive, a viscosity regulator and a colorant in addition to the surface coated metal particles (A), the layered substance (B) and the binder component (C). Moreover, it may comprise insulating particles such as silica particles and the like.

### Production Process of Discharge Gap-Filling Composition

In producing the discharge gap filling composition of the present invention, for example, the surface coated metal particles (A) and the binder component (C), and further optionally the layered substance (B) and the other components, such as the solvent, the filler, the curing catalyst etc, are dispersed and mixed using a disper, a kneader, a 3-roll mill, a bead mill or an autorotation type stirrer. In the mixing, heating at a sufficient temperature may be conducted in order to attain favorable compatibility. After the dispersing and mixing, the curing accelerating agent may be added and mixed optionally.

### <Electrostatic Discharge Protector>

The electrostatic discharge protector of the present invention is used as a protective circuit for releasing an over current to earth in order to protect a device at the time of electrostatic discharging. At the time of normal operating at a low voltage, the electrostatic discharge protector of the present invention shows a high electric resistance value and feeds a current into the device without releasing to earth. While, when electrostatic discharge is caused, it shows a low electric resistance value promptly, an over current is released to earth and thereby the electrostatic discharge protector prevents the device from overcurrent feeding. When the transient phenomenon of electrostatic discharging is dissolved, the electric resistance value returns to a high electric resistance value and the electrostatic discharge protector feeds a current to the device. In the electrostatic discharge protector of the present invention, the discharge gap is filled with the discharge gap-filling member formed from the discharge gap filling composition containing the insulating binder component (C). Therefore, leakage current does not generate at the time of normal operating. For example, when a voltage of not more than DC10V is applied between the electrodes, the resistance value can be made to be not less than 10¹⁰Ω and thereby electrostatic discharge protection can be attained.

The electrostatic discharge protector of the present invention comprises at least two electrodes and one discharge gap-filling member. The two electrodes are disposed in a definite distance. The distance between the two electrodes is a discharge gap. The discharge gap-filling member is filled in this discharge gap. That is to say, the two electrodes are connected through the discharge gap-filling member. The discharge gap-filling member is formed by the discharge gap filling composition as described above. The electrostatic discharge protector of the present invention can be produced using the discharge gap filling composition by forming the discharge gap-filling member in the following manner.

That is, the discharge gap filling composition is firstly prepared in the above process, and then the composition is applied so as to contact with two electrodes on the substrate for forming the discharge gap by potting, screen printing or other method, and solidified or cured if necessary with heating to form the discharge gap-filling member on the substrate such as a flexible wiring board and the like.

The electrostatic discharge protector has a discharge gap distance of preferably not more than 500 μm, more preferably not less than 5 μm and not more than 300 μm, furthermore preferably not less than 10 μm and not more than 150 μm. When the discharge gap distance is over 500 μm, although even if the width of the electrodes for forming the discharge gap is set to be wide, the protector sometimes operates, it is easily to cause unevenness of electrostatic discharge performance in each product and it is difficult to conduct downsizing in the electrostatic discharge protector. While, when the discharge gap distance is less than 5 μm, is also easily to cause unevenness of electrostatic discharge performance in each product due to the dispersion of the surface coated metal particles (A) and the layered substance (B) and also to cause short circuit. Herein, the discharge gap distance means the shortest distance between the electrodes.

The shape of the preferable electrode of the electrostatic discharge protector can be set arbitrarily with matching to the condition of the circuit board. In consideration of downsizing, the shape is a film having a rectangular cross section orthogonal to the thick direction and having a thickness of, for example, 5 to 200 μm. The preferable width of the electrodes of the electrostatic discharge protector is not less than 5 μm, and the electrode width is preferably wider because energy at the time of electrostatic discharging can be diffused. While when the electrode width of the electrostatic discharge protector has a sharp shape and is less than 5 μm, the periphery members including the electrostatic discharge protector itself are damaged largely because energy at the time of electrostatic discharging concentrates.

In the discharge gap filling composition of the present invention, the adhesion to a base provided with the discharge gap is sometimes insufficient due to the material of the base, electrostatic discharge has very high energy and the volume occupancy of the surface coated metal particles (A) is high. Accordingly, when the discharge gap-filling member is formed and then the protective layer of the resin composition is provided so as to cover this discharge gap-filling member, the high voltage resistance is given and the repeating resistance is improved and also it is possible to prevent the electronic circuit board from contamination caused by falling of the surface coated metal particles (A) which volume occupancy is high.

Examples of the resin used for the protecting layer are a natural resin, a modified resin and an oligomer synthetic resin.

As the natural resin, rosin is a typical resin. Examples of the modified resin are a rosin derivative and a rubber derivative. Examples of the oligomer synthetic resin are an epoxy resin, an acrylic resin, a maleic acid derivative, a polyester resin, a melamine resin, a polyurethane resin, a polyimide resin, a polyamic acid resin, a polyimide/amide resin and a silicone resin.

The resin composition preferably contains a curing resin capable of being cured by heat or an ultraviolet ray in order to keep the coated film strength.

Examples of the thermosetting resin are a carboxyl group-containing polyurethane resin, an epoxy compound, a combination of an epoxy compound with a compound containing an acid anhydride group, a carboxyl group, an alcoholic group or an amino group, and a combination of a carbodiimide-containing compound with a compound containing a carboxyl group, an alcoholic group or an amino group.

Examples of the epoxy resin are epoxy compounds having two or more epoxy groups in one molecule, such as a bisphenol A type epoxy resin, a hydrogenated bisphenol A type epoxy resin, a brominated bisphenol A type epoxy resin, a bisphenol F type epoxy resin, a novolac type epoxy resin, a phenol novolac type epoxy resin, a cresol novolac type epoxy resin, an alicyclic epoxy resin, a N-glycydyl type epoxy resin, a bisphenol A novolac type epoxy resin, a chelate type epoxy resin, a glyoxal type epoxy resin, an amino group-containing epoxy resin, a rubber modified epoxy resin, a dicyclopentadiene phenolic type epoxy resin, a silicone modified epoxy resin and a ε-caprolactone modified epoxy resin.

In order to give flame resistance, an epoxy compound having a structure that a halogen atom such as chlorine atom or bromine atom, and a phosphorus atom and the like is introduced may be used. Furthermore, it is possible to use a bisphenol S type epoxy resin, a diglycidyl phthalate resin, a heterocyclic epoxy resin, a bixylenol type epoxy resin, a biphenol type epoxy resin and a tetraglycidyl xylenoyl ethane resin.

It is preferred to use an epoxy compound having two or more epoxy groups in one molecule as the epoxy compound, but it is possible to simultaneously use an epoxy compound having only one epoxy group in one molecule. An example of the compound containing a carboxyl group is an acrylate compound, which is not particularly limited. The alcoholic group-containing compound and the amino group-containing compound are not also particularly limited.

Examples of the ultraviolet ray curing resin are an acrylic copolymer which is a compound containing two or more ethylenic unsaturated groups, an epoxy(meth)acrylate resin and a urethane(meth)acrylate resin.

The resin composition for forming the protective layer can optionally contain a curing accelerating agent, a filler, a solvent, a foaming agent, a defoaming agent, a leveling agent, a lubricant, a plasticizer, an anticorrosive agent, a viscosity regulating agent and a colorant.

Although the thickness of the protective layer is not particularly limited, it is preferred that the protective layer completely cover the discharge gap filling member formed from the discharge gap filling composition. When the protective layer has a defect, there is strong possibility that crack will be generated by high energy at the time of electrostatic discharging.

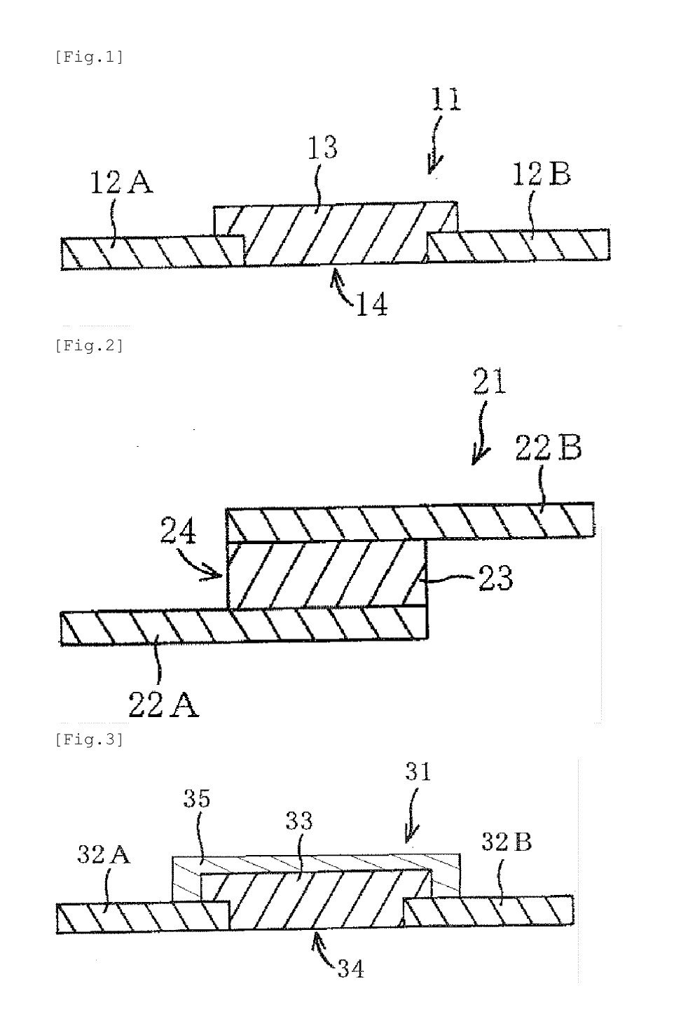

FIG. 1 is a longitudinal cross section showing an electrostatic discharge protector 11, which is one embodiment of the electrostatic discharge protector of the present invention. The electrostatic discharge protector 11 is formed from an electrode 12A, an electrode 12B and a discharge gap-filling member 13. The electrode 12A and electrode 12B are disposed so that their axial directions are identical and their head surfaces are faced each other. A discharge gap 14 is formed between the head surfaces of the electrodes 12A and 12B faced each other. The discharge gap-filling member 13 is filled in the discharge gap 14 so as to cover the head surface of the electrode 12A faced to the head surface of the electrode 12B and the head surface of the electrode 12B faced to the head surface of the electrode 12A from the upper side and to be contact with the head surfaces. The width of the discharge gap 14, namely the distance of the head surfaces of the electrodes 12A and 12B faced each other is preferably not less than 5 μm and not more than 300 μm.

FIG. 2 is a longitudinal cross section showing an electrostatic discharge protector 21, which is another embodiment of the electrostatic discharge protector of the present invention. The electrostatic discharge protector 21 is formed from an electrode 22A, an electrode 22B and a discharge gap-filling member 23. The electrode 22A and electrode 22B are parallel disposed so that they are piled up in their head parts in the vertical direction. A charge gap 24 is formed on the parts of the electrodes 22A and 22B piled up each other in the vertical direction. The discharge gap-filling member 23 has a rectangle cross-section and is filled in the discharge gap 24. The width of the discharge gap 24, namely distance between the electrodes 22A and 22B in the part where the electrodes 22A and 22B are piled up in the vertical direction is preferably not less than 5 μm and not more than 300 μm.

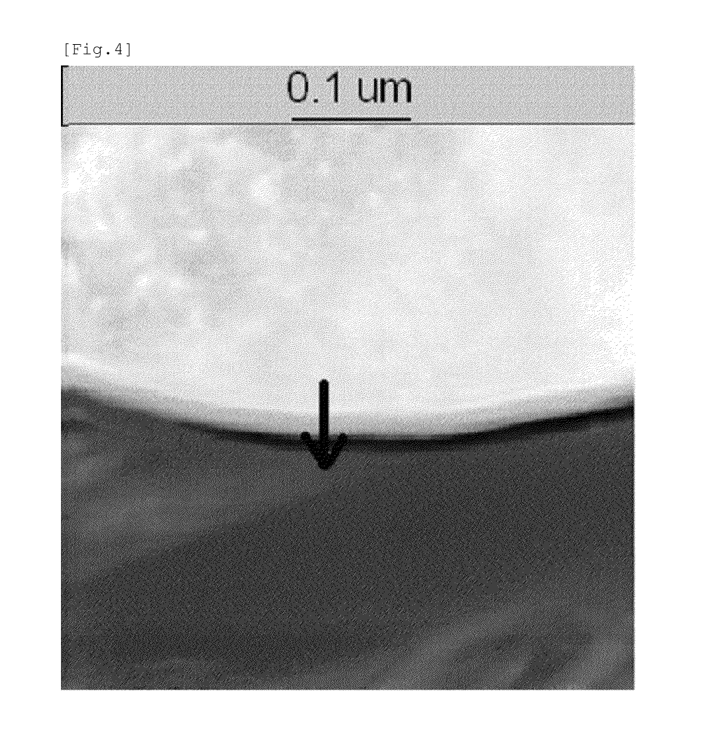

FIG. 3 is a longitudinal cross section showing an electrostatic discharge protector 31, which is one embodiment of the electrostatic discharge protector of the present invention. The electrostatic discharge protector 31 is obtainable by providing a protective layer in the electrostatic discharge protector 11 and is formed from an electrode 32A, an electrode 32B, a discharge gap-filling member 33 and a protective layer 35. The electrode 32A and electrode 32B are disposed so that their axial directions are identical and their head surfaces are faced each other. A discharge gap 34 is formed between the head surfaces of the electrodes 32A and 32B faced each other. The discharge gap-filling member 33 is filled in the discharge gap 34 so as to cover the head surface of the electrode 32A faced to the head surface of the electrode 32B and the head surface of the electrode 32B faced to the head surface of the electrode 32A from the upper side and to be contact with the head surfaces. The protective layer 35 is provided to cover the surface of the discharge gap-filling member 33 except for the bottom thereof. The width of the discharge gap 34, namely the distance of the head surfaces of the electrodes 32A and 32B faced each other is preferably not less than 5 μm and not more than 300 μm.

### EXAMPLE

The present invention will be described in more detail with reference to the following examples, but they should not limit it.

### <Preparation of Electrostatic Discharge Protector>

On a wiring substrate that a pair of electrode patterns having a film thickness of 12 μm, a discharge gap distance of 50 μm and an electrode width of 500 μm was formed on a polyimide film having a film thickness of 25 the discharge gap filling composition prepared by the method as described later was applied using a flat needle having a tip diameter of 2 mm and filled in the discharge gap so as to cover the electrode patterns. Thereafter, the wiring substrate was kept in a temperature controlled vessel at 120° C. for 60 min to form a discharge gap filling member. Thereafter, a silicon resin (Trade name: X14-B2334 manufactured by Momentive Inc.) was applied and completely covered on the electrostatic protector, and quickly put in a curing furnace at 120° C. and cured at 120° C. for 1 hr to form a protective film. Thus, an electrostatic discharge protector was prepared.

### <Evaluation Method for Insulating Properties at the Time of a Normal Operating Voltage>

Concerning the electrode parts provided in the both ends of the electrostatic discharge protector, the resistance at the time of application of DC10V was measured using an insulation-resistance meter “MEGOHMNETER SM-8220” and taken as a resistance at the time of normal operating.

A: The electric resistance value is not less than 10¹⁰Ω.
B: The electric resistance value is less than 10¹⁰Ω.

### <Evaluation Method for Operating Voltage>

Using a semiconductor electrostatic tester ESS-6008 (manufactured by NOISE LABORATORY Inc.), the peak current at an arbitrary applied voltage was measured. The resultant electrostatic discharge protector was set and the same applied voltage was applied thereon. The peak current was measured. When the peak current measured was 70% or more of the peak current in the case of no electrostatic discharge protector, its applied voltage was taken as an operating voltage.

A: The operating voltage is not less than 500V and less than 1000V.
B: The operating voltage is not less than 1000 and less than 2000V.
C: The operating voltage is not less than 2000V.

### <Evaluation Method for High Voltage Resistance>

The resultant electrostatic discharge protector was fixed in a semiconductor electrostatic tester ESS-6008 (manufactured by NOISE LABORATORY Inc.) and a 8 kV voltage was applied thereon 10 times, and then the resistance value in application of DC10V was measured using a insulation resistance meter MEGOHMMETER SM-8220. The resistance value was evaluated as high voltage resistance.

A: The resistance value is not less than 10¹⁰Ω.
B: The resistance value is not less than 10⁸Ω and less than 10¹⁰Ω.
C: The resistance value is less than 10⁸Ω.

### <Preparation Example 1 of Surface Coated Metal Particles (A)>

### Paste 1 Containing Surface Coated Al Particles

49 g of oxide film coated spherical aluminum particles manufactured by Toyo Aluminum K.K. (Trade Name: 08-0076, average particle diameter: 2.5 μm) was dispersed in 724 g of propylene glycol monomethylether to prepare a dispersion, and 169 g of ion exchange water and 32 g of 25% by mass ammonium water were added to the dispersion and stirred to prepare an aluminum powder slurry and the aluminum powder slurry was kept at 30° C. Next, 13.2 g of tetramethoxy silane was diluted with 13.2 g of propylene glycol monomethylether and this solution was dropped to the aluminum powder slurry at a definite rate over 12 hr. In the progress of hydrolysis of the tetraethoxy silane for forming films, surface covering of aluminum particles by a hydrolysis product of tetraethoxy silane was conducted.

After the dropping, the stirring was continued for 12 hr, and the temperature was kept at 30° C. Thereafter, the aluminum particles which surfaces were covered with the tetraethoxy silane hydrolysis product were washed with propylene glycol monomethyl ether three times and then the solvent was scattered at 40° C. to prepare a paste containing water and propylene glycol monomethylether having an aluminum solid content of 35% by mass.

For measuring the solid component, the paste extracted was dried at 120° C. for 1 hr and a resulted residue was prepared. The mass of the residue was divided by the mass of the original paste to determine a solid component. The scattering of the solvent at 40° C. was finished by confirming the fact that the solid component was 35% by mass.

The tetraethoxy silane hydrolysis product, which covered the surfaces of the spherical aluminum particles had a film thickness of about 20 to 30 nm and covered almost all of the surfaces of the spherical aluminum particles.

The covered part of the Al particle, which surface was covered with the tetraethoxy silane hydrolyzed product in Preparation Example 1 was analyzed by TEM&EDS (HF-2200 manufactured by Hitachi, Ltd.).

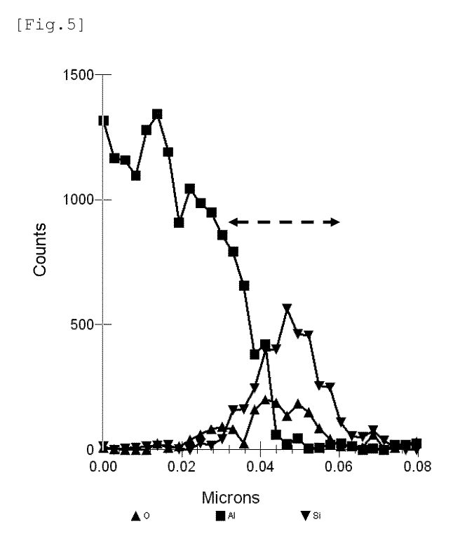

The TEM image is shown in FIG. 4. The results of element analysis (EDS) conducted in the direction indicated by the arrow (↓) in FIG. 4 are shown in FIG. 5. From the count amounts of Si (∇) and Al (□) elements in FIG. 5, and the TEM image in FIG. 4, it is understood that the thickness of the region indicated by ⇄ where Si is a main component is the thickness of the coated film and the thickness is about 20 to 30 nm.

### <Preparation Example 2 of Surface Coated Metal Particles (A)>

### Paste 2 Containing Surface Coated Al Particles

49 g of oxide film coated spherical aluminum particles manufactured by Toyo Aluminum K.K. (Trade Name: 08-0076, average particle diameter: 2.5 μm) was dispersed in 724 g of propylene glycol monomethylether to prepare a dispersion, and 169 g of ion exchange water and 32 g of 25% by mass ammonium water were added to the dispersion and stirred to prepare an aluminum powder slurry and the aluminum powder slurry was kept at 30° C. Next, 21.6 g of tetra-n-butyl titanate was diluted with 21.6 g of propylene glycol monomethylether and this solution was dropped to the aluminum powder slurry at a definite rate over 12 hr. In the progress of hydrolysis of the tetra-n-butyl titanate, surface covering of aluminum particles by a hydrolysis product of tetra-n-butyl titanate was conducted.

After the dropping, the stirring was continued for 12 hr, and the temperature was kept at 30° C. Thereafter, the aluminum particles which surfaces were covered with the tetra-n-butyl titanate hydrolysis product were washed with propylene glycol monomethyl ether three times and then the solvent was scattered at 40° C. to prepare a paste containing water and propylene glycol monomethylether having an aluminum solid content of 45% by mass.

For measuring the solid component, the paste extracted was dried at 120° C. for 1 hr and a resulted residue was prepared. The mass of the residue was divided by the mass of the original paste to determine a solid component. The scattering of the solvent at 40° C. was finished by confirming the fact that the solid component was 45% by mass.

### <Preparation Example 3 of Surface Coated Metal Particles (A)>

### Paste 3 Containing Surface Coated Al Particles

49 g of oxide film coated spherical aluminum particles manufactured by Toyo Aluminum K.K. (Trade Name: 08-0076, average particle diameter: 2.5 μm) was dispersed in 724 g of propylene glycol monomethylether to prepare a dispersion, and 169 g of ion exchange water and 32 g of 25% by mass ammonium water were added to the dispersion and stirred to prepare an aluminum powder slurry and the aluminum powder slurry was kept at 30° C. Next, 27.0 g of tetra-n-butyl zirconate was diluted with 27.0 g of propylene glycol monomethylether and this solution was dropped to the aluminum powder slurry at a definite rate over 12 hr. In the progress of hydrolysis of tetra-n-butyl zirconate, surface covering of aluminum particles by a hydrolysis product of tetra-n-butyl zirconate was conducted.

After the dropping, the stirring was continued for 12 hr, and the temperature was kept at 30° C. Thereafter, the aluminum particles which surfaces were covered with the tetra-n-butyl zirconate hydrolysis product were washed with propylene glycol monomethyl ether three times and then the solvent was scattered at 40° C. to prepare a paste containing water and propylene glycol monomethylether having an aluminum solid content of 66% by mass.

For measuring the solid component, the paste extracted after thoroughly stirring was dried at 120° C. for 1 hr and a resulted residue was prepared. The mass of the residue was divided by the mass of the original paste to determine a solid component. The scattering of the solvent at 40° C. was finished by confirming the fact that the solid component was 66% by mass.

### <Synthetic Example 1 of Binder Component (C)>

### Thermosetting Urethane Resin 1

To a reactor equipped with a stirrer, a thermometer and a condenser, 718.2 g of C-1015N (manufactured by Kuraray Co., Ltd. a polycarbonate diol having a raw material diol molar ratio of 1,9-nonane diol to 2-methyl-1,8-octane diol of 15:85, and a molecular weight of 964) as a polycarbonate diol, 136.6 g of 2,2-dimethylol butanoic acid (manufactured by Nippon Kasei Chemical Co., Ltd.) as a carboxyl group having dihydroxyl compound and 1293 g of diethylene glycol ethylether acetate (manufactured by Daicel Chemical Industries Ltd.) as a solvent were fed and all the raw materials were dissolved at 90° C. The temperature of the reaction solution was decreased to 70° C. and 237.5 g of methylene bis(4-cyclohexyl isocyanate) (manufactured by Sumica Bayer Urethane Co., Ltd. Trade Name “Desmodule-W”) was dropped as a polyisocyanate to the solution over 30 min through a dropping funnel. After the dropping, the reaction was carried out at 80° C. for 1 hr, at 90° C. for 1 hr and at 100° C. for 1.5 hr and then it was confirmed that almost of isocyanate was disappeared. Thereafter, 2.13 g of isobutanol (manufactured by Wako Pure Chemical Industries Ltd.) was dropped to the solution and reacted at 105° C. for 1 hr. The resultant carboxyl group containing urethane had a number average molecular weight of 6090 and a solid content acid value of 40.0 mgKOH/g. This urethane was diluted by adding γ-butylolactone so that the solid content was 45% by mass.

### <Synthetic Example 2 of Binder Component (C)>

### Thermosetting Urethane Resin 2

To a 5 L four-necked flask equipped with a stirrer, a cooling tube with an oil separator, a nitrogen introducing tube and a thermometer, 1000.0 g of PLACCEL CD-220 (Trade Name manufactured by Daicel Chemical Industries, Ltd. 1,6-hexane diol polycarbonate diol), 250.27 g (1.00 mol) of 4,4′-diphenyl methane diisocyanate and 833.51 g of γ-butylolactone were fed and the temperature of the mixture was increased to 140° C. The mixture was reacted at 140° C. for 5 hr to prepare a second diisocyanate. Thereafter, to the reaction solution, 288.20 g (1.50 mol) of anhydrous trimellitic acid as an anhydride group having polycarboxylic acid, 125.14 g (0.50 mol) of 4,4′-diphenylmethane diisocyanate and 1361.14 g of γ-butylolactone were fed and the temperature was increased to 160° C. and the mixture was reacted for 6 hr to prepare a resin having a number average molecular weight of 18,000. The resultant resin was diluted with γ-butylolactone to prepare a polyamide imide resin solution having a viscosity of 160 Pa·s and a nonvolatile component content of 52% by weight, namely an acid anhydride group-containing thermosetting urethane resin solution.

### Example 1

To 57 g of the paste 1 containing surface coated aluminum particles (solid content of 35% by mass) prepared in Preparation Example 1 and 1.0 g of “UF-G5” (artificial graphite fine powder, scale form, average particle diameter 3 μm, manufactured by Showa Denko K.K.) as the layered substance (B), 18.2 g of the thermosetting urethane resin 1 (solid content of 45% by mass) synthesized in Synthesis Example 1 and 0.63 g of an epoxy resin (JER604 manufactured by Japan Epoxy Resin Co., Ltd.) as a curing agent were added and stirred at 2000 rpm by a homogenizer for 15 min to prepare a discharge gap filling resin composition. The discharge gap filling resin composition had a mass occupancy of surface coated aluminum particles (A) of 67% by mass and that of the layered substance (B) of 3% by mass. Using the discharge gap filling resin composition, an electrostatic discharge protector was prepared by the above method. The resistance at the time of normal operating, the operating voltage and the high voltage resistance were evaluated.

The results are shown in Table 1.

### Example 2

To 57 g of the paste 1 containing surface coated aluminum particles (solid content of 35% by mass) prepared in Preparation Example 1, 18.2 g of the thermosetting urethane resin 1 (solid content of 45% by mass) synthesized in Synthesis Example 1 and 0.63 g of an epoxy resin (JER604 manufactured by Japan Epoxy Resin Co., Ltd.) as a curing agent were added and stirred at 2000 rpm by a homogenizer for 15 min to prepare a discharge gap filling resin composition. The discharge gap filling resin composition had a mass occupancy of surface coated aluminum particles (A) of 70% by mass and that of the layered substance (B) of 0% by mass. Using the discharge gap filling resin composition, an electrostatic discharge protector was prepared by the above method. The resistance at the time of normal operating, the operating voltage and the high voltage resistance were evaluated. The results are shown in Table 1.

### Example 3

To 57 g of the paste 1 containing surface coated aluminum particles (solid content of 35% by mass) prepared in Preparation Example 1 and 1.0 g of “UF-G5” (artificial graphite fine powder, scale form, average particle diameter 3 μm, manufactured by Showa Denko K.K.) as the layered substance (B), 15.8 g of the thermosetting urethane resin 2 (nonvolatile component content of 52% by mass) synthesized in Synthesis Example 2 and 1.58 g of YH-434 (Trade Name, amine type epoxy resin, epoxy equivalent weight of about 120, 4 epoxy groups/molecule manufactured by Thoto Kasei Co., Ltd.) as a curing agent were added and stirred at 2000 rpm by a homogenizer for 15 min to prepare a discharge gap filling resin composition. The discharge gap filling resin composition had a mass occupancy of surface coated aluminum particles (A) of 65% by mass and that of the layered substance (B) of 3% by mass. Using the discharge gap filling resin composition, an electrostatic discharge protector was prepared by the above method. The resistance at the time of normal operating, the operating voltage and the high voltage resistance were evaluated. The results are shown in Table 1.

### Example 4

To 44 g of the paste 2 containing surface coated aluminum particles (solid content of 45% by mass) prepared in Preparation Example 2, 1.0 g of “UF-G5” (artificial graphite fine powder, scale form, average particle diameter 3 μm, manufactured by Showa Denko K.K.) as the layered substance (B) and 13 g of propylene glycol monomethylether, 18.2 g of the thermosetting urethane resin 1 (solid content of 45% by mass) synthesized in Synthesis Example 1 and 0.63 g of an epoxy resin (Trade Name JER604, manufactured by Japan Epoxy Resin Co., Ltd.) as a curing agent were added and stirred at 2000 rpm by a homogenizer for 15 min to prepare a discharge gap filling resin composition. The discharge gap filling resin composition had a mass occupancy of surface coated aluminum particles (A) of 67% by mass and that of the layered substance (B) of 3% by mass. Using the discharge gap filling resin composition, an electrostatic discharge protector was prepared by the above method. The resistance at the time of normal operating, the operating voltage and the high voltage resistance were evaluated. The results are shown in Table 1.

### Example 5

To 30 g of the paste 3 containing surface coated aluminum particles (solid content of 36% by mass) prepared in Preparation Example 3, 1.0 g of “UF-G5” (artificial graphite fine powder, scale form, average particle diameter 3 μm, manufactured by Showa Denko K.K.) as the layered substance (B) and 27 g of propylene glycol monomethyl ether, 18.2 g of the thermosetting urethane resin 1 (solid content of 45% by mass) synthesized in Synthesis Example 1 and 0.63 g of an epoxy resin (Trade Name JER604 manufactured by Japan Epoxy Resin Co., Ltd.) as a curing agent were added and stirred at 2000 rpm by a homogenizer for 15 min to prepare a discharge gap filling resin composition. The discharge gap filling resin composition had a mass occupancy of surface coated aluminum particles (A) of 67% by mass and that of the layered substance (B) of 3% by mass. Using the discharge gap filling resin composition, an electrostatic discharge protector was prepared by the above method. The resistance at the time of normal operating, the operating voltage and the high voltage resistance were evaluated. The results are shown in Table 1.

### Comparative Example 1

The procedure of Example 1 was repeated except for using 20 g of oxide film coated spherical aluminum particles 08-0076 (average particle diameter 2.5 mm) manufactured by Toyo Aluminum K.K. in place of 57 g of the paste 1 containing surface coated aluminum particles prepared in Preparation Example 1, to prepare a discharge gap filling resin composition. The discharge gap filling resin composition had a mass occupancy of surface uncoated aluminum particles of 67% by mass and that of the layered substance (B) of 3% by mass.

Using the discharge gap filling resin composition, an electrostatic discharge protector was prepared by the above method. The resistance at the time of normal operating, the operating voltage and the high voltage resistance were evaluated.

The results are shown in Table 1.

### Comparative Example 2

The procedure of Example 1 was repeated except for using 20 g of oxide film coated spherical aluminum particles 08-0076 (average particle diameter 2.5 μm) manufactured by Toyo Aluminum K.K. in place of 57 g of the paste 1 containing surface coated aluminum particles prepared in Preparation Example 1, and using 0.76 g of fumed silica (Cabosil M-5 manufactured by Cabot Co., Ltd.), to prepare a discharge gap filling resin composition. The discharge gap filling resin composition had a mass occupancy of spherical aluminum particles and fumed silica of 67% by mass and that of the layered substance (B) of 3% by mass.

Using the discharge gap filling resin composition, an electrostatic discharge protector was prepared by the above method. The resistance at the time of normal operating, the operating voltage and the high voltage resistance were evaluated.

The results are shown in Table 1.

TABLE 1

| | Resistance at | | |
|---|---|---|---|
| | the time of | | |
| | normal | Operating | High voltage |
| | operating | voltage | resistance |
| Example 1 | A | A | A |
| Example 2 | A | B | A |
| Example 3 | A | A | A |
| Example 4 | A | A | A |
| Example 5 | A | A | A |
| Comparative | A | A | C |
| Example 1 | | | |
| Comparative | A | A | C |
| Example 2 | | | |

As is clear from the results of Table 1, the electrostatic discharge protector formed using the discharge gap filling composition which comprises the metal particles (A) which surfaces are covered with a specific metal alkoxide hydrolyzed product and the binder component (C) has excellent resistance at the time of normal operating, operating voltage and high voltage resistance. Moreover, in the case of the combined use of the layered substance (B), the resultant electrostatic discharge protector has more excellent properties on operating voltage.

From the difference with Comparative Example 2, in the case that the surface uncoated metal particles and the fine powdery oxide are mixed mechanically and used to an electrostatic discharge protector, it is found that the high voltage resistance is insufficient.

### POSSIBILITY OF INDUSTRIAL USE

Using the discharge gap filling composition containing the metal particles (A) which surfaces are covered with a specific metal alkoxide hydrolyzed product and the binder component (C), the electrostatic discharge protector having a free shape can be prepared and thereby the downsizing and decrease in cost in a measure of ESD can be attained. This electrostatic discharge protector can be provided on electronic circuit boards such as a flexible electronic circuit board and the like, and these electronic circuit boards can be provided on electronic devices.

### DESCRIPTION OF MARKS

11 . . . Electrostatic discharge protector
12A . . . Electrode
12B . . . Electrode
13 . . . Discharge gap-filling member
14 . . . Discharge gap
21 . . . Electrostatic discharge protector
22A . . . Electrode
22B . . . Electrode
23 . . . Discharge gap-filling member
24 . . . Discharge gap
31 . . . Electrostatic discharge protector
32A . . . Electrode
32B . . . Electrode
33 . . . Discharge gap-filling member
34 . . . Discharge gap
35 . . . Protective layer

1. A discharge gap filling composition comprising metal particles (A) obtainable by covering metal particles with a hydrolyzed product of a metal alkoxide represented by the following formula (1) and a binder component (C);
R—O—[M(OR)₂—O—]ₙ—R (1)
wherein M is a metal atom, O is an oxygen atom, R is an alkyl group of 1 to 20 carbon atoms, all or a part of R's may be the same as or different each other, and n is an integer of 1 to 40.

2. The discharge gap filling composition according to claim 1 wherein the element M in the formula (1) is silicon, titanium, zirconium, tantalum or hafnium.

3. The discharge gap filling composition according to claim 1 wherein the metal particles of the metal particles (A) are oxide film coated metal particles.

4. The discharge gap filling composition according to claim 3 wherein the metal of the oxide film coated metal particles is at least one selected from the group consisting of manganese, niobium, zirconium, hafnium, tantalum, molybdenum, vanadium, nickel, cobalt, chromium, magnesium, titanium and aluminum.

5. The discharge gap filling composition according to claim 1 further comprising a layered substance (B) together with the metal particles (A) and the binder component (C).

6. The discharge gap filling composition according to claim 5 wherein the layered substance (B) is at least one selected from the group consisting of a clay mineral crystal (B1) and a layered carbon material (B2).

7. The discharge gap filling composition according to claim 5 wherein the layered substance (B) is the layered carbon material (B2).

8. The discharge gap filling composition according to claim 7 wherein the layered carbon material (B2) is at least one selected from the group consisting of carbon nano tube, gas phase grown carbon fiber, carbon fullerene, graphite and a carbyne carbon material.

9. The discharge gap filling composition according to claim 1 wherein the binder component (C) comprises a thermosetting or activated energy curing composition.

10. The discharge gap filling composition according to claim 1 wherein the binder component (C) comprises a thermosetting urethane resin.

11. An electrostatic discharge protector comprising two electrodes for forming a discharge gap, and a discharge gap filling-member that is filled in the discharge gap wherein the discharge gap-filling member comprises the discharge gap filling composition as claimed in claim 1 and the discharge gap has a distance of 5 to 300 μm.

12. The electrostatic discharge protector according to claim 11 further comprising a protective layer which covers all or a part of the surface of the discharge gap-filling member.

13. An electronic circuit board provided with the electrostatic discharge protector as claimed in claim 11.

14. The electronic circuit board according to claim 13, which is a flexible electronic circuit board.

15. An electronic device provided with the electronic circuit board as claimed in claim 13.
